(19) United States
(12) Patent Application Publication
(10) Pub. No.: US 2019/0157355 A1
(43) Pub. Date: May 23, 2019

(54) TOUCH SCREEN PANEL AND MANUFACTURING METHOD THEREOF

(71) Applicant: Wuhan China Star Optoelectronics Semiconductor Display Technology Co. Ltd., Wuhan, Hubei (CN)

(72) Inventor: Jian YE, Shenzhen, Guangdong (CN)

(21) Appl. No.: 15/746,599

(22) PCT Filed: Dec. 18, 2017
(86) PCT No.: PCT/CN2017/116833

§ 371 Date: Oct. 25, 2018

(30) Foreign Application Priority Data
Nov. 22, 2017 (CN) 201711188931.9

(51) Int. Cl. H01L 27/32; H01L 51/52; H01L 51/56; G06F 3/041

(52) U.S. Cl. CPC H01L 27/323; H01L 27/3258; H01L 27/3276; H01L 27/3246; H01L 27/3248; H01L 27/124; H01L 51/56; G06F 3/0412; G06F 3/0416; H01L 2227/323; H01L 51/5209

(57) ABSTRACT

A touch screen panel and a method of manufacturing touch screen panel are provided. The touch screen panel includes a TFT array substrate; a first protecting layer positioned on the TFT array substrate; a plurality of metal traces interval positioned on the first protecting layer; a second protecting layer covering the metal traces and the first protecting layer; and an anode, a pixel defining layer, a light-emitting layer and a plurality of interval positioned cathodes are sequentially positioned on the second protecting layer, the cathodes are used to be touch electrode layer, each of the cathodes is electrically connecting to the correspondingly metal trace. Because the invention does not need to position another touch screen electrode/panel, reduces the element, which decreases thickness of the OLED touch screen panel, it beneficial to light weight development.

### RELATED APPLICATIONS

The present application is a National Phase of International Application Number PCT/2017/116833, filed Dec. 18, 2017, and claims the priority of China Application No. 201711188931.9, filed Nov. 22, 2017.

### FIELD OF THE DISCLOSURE

The disclosure relates to a display technical field, and more particularly to a touch screen panel and a method of manufacturing touch screen panel.

### BACKGROUND

The Organic light-emitting diodes (OLED) has numerous of advantages such as low driving voltage, fast response speed, high effectiveness of emitting, wide view angle, wide working temperature, so that it is beneficial to thin-light, low power consumption and curving design of display element. Currently, the existing touch panel product structure base on OLED which needs to respectively manufacturing OLED display panel and touch panel, and pasting these two panels by gel materials to form an entire touch screen device. This structure will increases entire thickness of the OLED device, and not beneficial to light-thin development of product.

### SUMMARY

A technical problem to be solved by the disclosure is to provide a touch screen panel and a method of manufacturing touch screen panel.

An objective of the disclosure is achieved by following embodiments. In particular, a touch screen panel includes a TFT array substrate; a first protecting layer positioned on the TFT array substrate; a plurality of metal traces interval positioned on the first protecting layer; a second protecting layer covering the metal traces and the first protecting layer; and an anode, a pixel defining layer, a light-emitting layer and a plurality of interval positioned cathodes are sequentially positioned on the second protecting layer, the cathodes are used to be touch electrode layer, each of the cathodes is electrically connecting to the correspondingly metal traces.

In an embodiment, the first protecting layer is passivation layer and made by inorganic materials; the second protecting layer is planarization layer and made by organic materials.

In an embodiment, the first protecting layer is planarization layer and made by organic materials; the second protecting layer is passivation layer and made by inorganic materials.

In an embodiment, a plurality of first holes are formed on the second protecting layer, a plurality of second holes are formed on the pixel defining layer, each of the first holes is connecting to one of the second hole, and each of the cathodes is electrically connecting with the correspondingly metal trace by one of the first hole and one of the second hole.

In an embodiment, a first connecting hole is formed on the first protecting layer, a second connecting hole is formed on the second protecting layer and connecting to the first connecting hole, the anode is electrically connecting to a drain electrode of the TFT array substrate according to the first connecting hole and the second connecting hole.

In an embodiment, the touch screen panel further comprising a controller, the controller is electrically connected by the metal trace and the cathode, the controller has touch and display driving controlling function.

In an embodiment, material of the metal trace is one of Cu, Ag, Al, Ti, Mo.

According to another aspect of the disclosure, the disclosure further provides a method of manufacturing touch screen panel. The method of manufacturing touch screen panel, comprising

providing TFT array substrate;

forming a first protecting layer on the TFT array substrate;

forming a plurality of metal traces interval positioned on the first protecting layer;

forming a second protecting layer covering the metal traces and the first protecting layer;

forming a plurality of anodes interval positioned on the second protecting layer;

forming a pixel defining layer on the second protecting layer, the pixel defining layer is forming an accommodation region surround and above each of the anodes;

forming a light-emitting layer on each of the anodes, the light-emitting layer is accommodating in the accommodation region;

forming a plurality of cathodes which could be touch electrode layer and positioned above the light-emitting layer, the cathodes are interval positioned, each of the cathodes is electrically connecting to the correspondingly metal trace.

In an embodiment, in the step of “forming a second protecting layer on the metal traces and the first protecting layer”, which forming a plurality of first holes on the second protecting layer, and each of first holes is correspondingly positioned a metal trace; in the step of “forming a pixel defining layer on the second protecting layer, the pixel defining layer is forming an accommodation region surround and above each of the anodes”, which forming a plurality of second holes on the pixel defining layer, each of the second hole is connecting with the first hole, each of the cathodes is electrically connecting to the correspondingly metal trace by the first hole and the second hole.

In an embodiment, the first protecting layer is passivation layer and made by inorganic materials; the second protecting layer is planarization layer and made by organic materials; or the first protecting layer is planarization layer and made by organic materials; the second protecting layer is passivation layer and made by inorganic materials.

In an embodiment, each of the cathodes comprises a cathode main body and a cathode connecting portion which extending by the cathode main body, the cathode main body is covering the light-emitting layer, the cathode connecting portion is electrically connecting with the correspondingly metal trace by pass through the first hole and the second hole.

In an embodiment, each of the anodes comprises an anode main body and an anode connecting portion which extending by the anode main body, the anode main body is accommodating in the pixel defining layer, the anode main body is positioned between the second protecting layer and the light-emitting layer, the anode connecting portion pass through the second connecting hole and the first connecting hole for electrically connecting with the drain such that achieves to electrically connection between the anode and the drain.

The touch screen panel and the manufacturing method thereof, comprising a plurality of cathode are interval positioned, the cathode is used to be touch electrode layer. The cathode is electrically connecting to the metal trace by the controller electrically connecting with the metal trace, so that is does not need to position another touch electrode/panel, reduces the element, decreases thickness of the touch screen display, it beneficial to thin-light development. Further, controller has touch and display driving controlling function, greatly reduces thickness of entire device; at the same time, reduces number of electrical element, reduce manufacturing process, decreases cost.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a sectional view of a touch screen panel of the disclosure;

FIG. 2 is a connection schematic view between the cathode and controller of a touch screen panel shown in FIG. 1; and

FIG. 3 is a manufacturing method flow chart of a touch screen panel of the disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

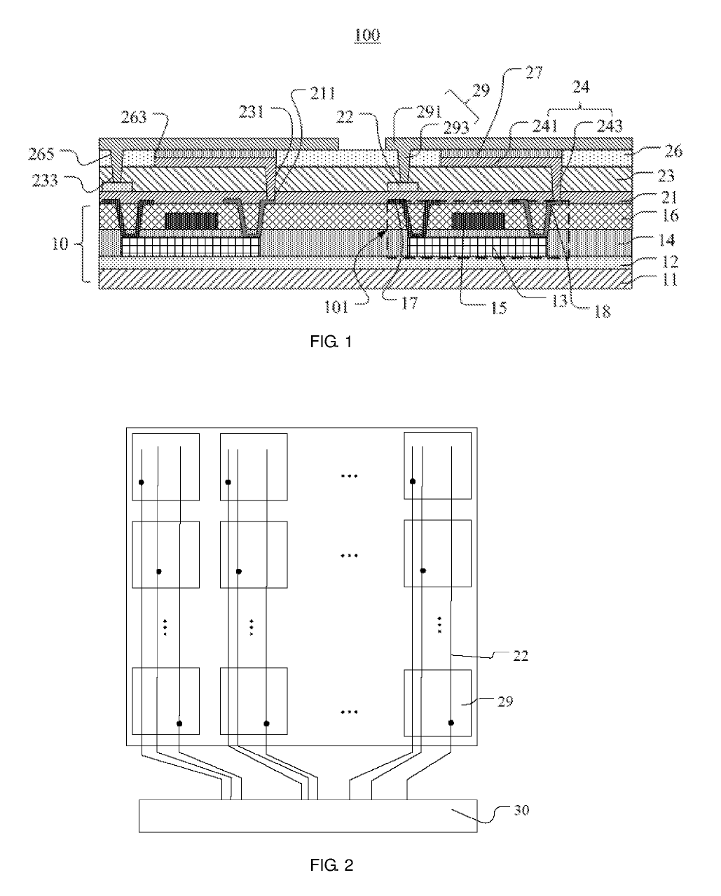

Please refer to the FIG. 1. A touch screen panel 100 is provided by this disclosure. In this embodiment, the touch screen panel 100 is OLED touch screen panel.

The touch screen panel 100, comprising a TFT array substrate 10; a first protecting layer 21 positioned on the TFT array substrate 10; a plurality of metal traces 22 (only illustrates two metal traces in FIG. 1) interval positioned on the first protecting layer 21; a second protecting layer 23 is covering the metal traces 22 and the first protecting layer 21; and an anode 24, a pixel defining layer 26, a light-emitting layer 27 and a plurality of interval positioned cathodes 29 are sequentially positioned on the second protecting layer 23, the cathodes 29 are also used to be touch electrode layer, each of the cathodes 29 is electrically connecting to the correspondingly metal trace 22.

Specifically, the TFT array substrate 10 includes substrate 11, buffer layer 12 and a plurality of TFT transistor 101 (only illustrates two transistors in FIG. 1). In this embodiment, material of the substrate 11 is polyimide (PI) or glass. The buffer layer 12 is covering the substrate 11. Each of the TFT transistors 101 includes an active layer 13, a grid insulating layer 14, a grid electrode 15, a dielectric layer 16, a source electrode 17 and a drain electrode 18. The active layer 13 is pasting on the buffer layer 12. The grid insulating layer 14 is covering the buffer layer 12 and the active layer 13. The gird electrode 15 is positioned on the grid insulating layer 14. The dielectric layer 16 is covering the grid electrode 15 and the grid insulating layer 14. The source electrode 17 is positioned on the dielectric layer 16 and connecting with the active layer 13. The drain electrode 18 is spaced by the source electrode 17 and positioned on the dielectric layer 16, and the drain electrode 18 is connecting with the active layer 13. Each of the drain electrodes 18 of the TFT transistors 101 is electrically connecting with one anode 24.

The first protecting 21 is covering the source electrode 17, the drain electrode 18 and the dielectric layer 16. The first protecting layer 21 is passivation layer, and made by inorganic materials. Preferably, material of the first protecting layer 21 could be SiNₓ or SiO₂. A plurality of first connecting hole 211 are formed on the first protecting layer 21. Each of the first connecting holes 211 is correspondingly positioned to one of the drain electrode 18.

A plurality metal traces 22 are interval positioned on a side of the first protecting layer 21 which far away the dielectric layer 16. The material of the metal traces 22 is a metal or alloy material which has better property of conductivities, such as at least one of Cu, Ag, Al, Ti, Mo.

The second protecting layer 23 is covering the first protecting 21 and the metal traces 22. The first protecting layer 21 is positioned between the second protecting layer 23 and the dielectric layer 16. The second protecting layer 23 is planarization layer, and made by organic materials. A plurality of second connecting hole 231 are formed on the second protecting layer 23. Each of the second connecting holes 231 is correspondingly connecting with one of the first connecting hole 211. The second protecting layer 23 is forming a first hole 233 that corresponding to each of metal traces 22. It is noted that, each of the first connecting hole 211 and the correspondingly second connecting hole 231 only needs to connect each other.

A plurality of anode 24 are interval positioned on a side of the second protecting layer 23 which far away the first protecting layer 21. Each of the anodes 24 is electrically connecting with the correspondingly drain electrode 18 by one of the first connecting hole 211 and one of the second connecting hole 231.

Further, each of the anodes 24 comprises an anode main body 241 and an anode connecting portion 243 which extending by the anode main body 241. The anode main body 241 is positioned on the second protecting layer 23. Each of the anodes connecting portions 243 pass through one of the first connecting hole 211 and one of the second connecting hole 231 such that achieves to the anode 24 is electrically connecting with the drain electrode 18.

The pixel defining layer 26 is covering the second protecting layer 23. The pixel defining layer 26 is forming an accommodation region 263 surround and above each of the anodes 24. The second protecting layer 23 is positioned between the first protecting layer 21 and the pixel defining layer 26. The pixel defining layer 26 is forming a plurality of second holes 265. Each of the second holes 265 is correspondingly positioned and connecting with one of the first hole 233. The accommodation region 263 is located above the anode main body 241.

The light-emitting layer 27 is accommodated in the accommodation region 263. The light-emitting layer 27 is positioned a surface of the anode main body 241 which far away the second protecting layer 23. The anode main body 241 is positioned between the light-emitting layer 27 and the second protecting layer 23.

A plurality of the cathodes 29 is interval positioned on the light-emitting layer 27. The cathode 29 is also used to be touch electrode layer. The light-emitting layer 27 is positioned between the anode 24 and the cathode 29. Each of the cathode 29 is connecting with the correspondingly metal traces 22 by one of the first hole 233 and one of the second hole 265, such that achieved to electrically connecting between the cathode 26 and the metal traces 22.

Further, each of the cathodes 29 comprises a cathode main body 291 and a cathode connecting portion 293 which bending toward and extending to the metal traces 22 by the cathode main body 291. The cathode main body 291 is positioned on the light-emitting layer 27. The light-emitting layer 27 is positioned between the anode main body 241 and the cathode main body 291. The cathode connecting portion 293 is electrically connecting with the correspondingly metal trace 22 by pass through the first hole 233 and the second hole 235. Therefore, it achieves to electrically connect between the cathode 29 and the metal trace 22.

In another embodiment, the first protecting layer 21 is planarization layer, and made by organic materials; the second protecting layer 23 is passivation layer, and made by inorganic materials. Preferably, material of the first protecting layer 21 could be SiNₓ or SiO₂.

Because of the cathode 29 is used to be touch electrode layer and the cathode 29 is electrically connecting with the metal trace 22, it does not need to another touch screen panel, reduces the elements such that decreases thickness of the OLED touch screen panel, it beneficial to light weight and thinner development. In addition, it also enhance open ratio of the emitting pixel of the touch screen panel 100, because of the cathodes 29 are not positioned on entirely surface of the touch screen panel 100.

Further, please refer to FIG. 2. The touch screen panel 100 further comprises a controller 30. The controller 30 is electrically connected by the metal trace 22 and the cathode 29. The controller 30 has touch and display driving controlling function, which integrating two chips has touch and display driving controlling function respectively into one controller. Because the touch and display are using same controller 30, greatly reduces thickness of whole touch screen panel; and also reduces number of the electrically element, reduces manufacturing step, decreases cost.

The touch screen panel 100 could be applied to devices has display function such as liquid crystal television, smart phone, digital camera, tablet, wearing watch, notebook and so on.

In this embodiment, the buffer layer 12, a grid insulating layer 14 and dielectric layer 16 are made by inorganic materials such as SiNₓ or SiO₂.

It could be noted that, the buffer layer 12 could be omitted.

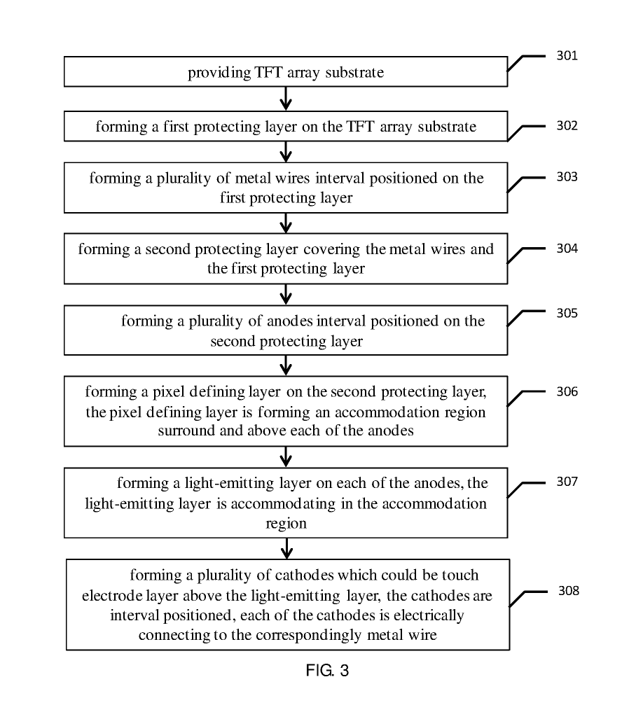

A method of manufacturing touch screen panel is also provided by this disclosure. Please refer to FIG. 3, the method comprises the following steps.

301, providing TFT array substrate.

Specifically, the TFT array substrate includes substrate, buffer layer and a plurality of TFT transistor. In this embodiment, material of the substrate is glass. The buffer layer is covering the substrate. Each of the TFT transistors includes an active layer, a grid insulating layer, a grid electrode, a dielectric layer, a source electrode and a drain electrode. The active layer is pasting on the buffer layer. The grid insulating layer is covering the buffer layer and the active layer. The gird electrode is positioned on the grid insulating layer. The dielectric layer is covering the grid electrode and the grid insulating layer. The source is positioned on the dielectric layer and connecting with the active layer. The drain electrode is spaced by the source electrode and positioned on the dielectric layer, and the drain electrode is connecting with the active layer.

302, forming a first protecting layer on the TFT array substrate;

Further, a first connecting hole is forming on the first protecting layer, each of the first connecting holes is corresponding to a drain electrode of one of the TFT transistor.

303, forming a plurality of metal traces interval positioned on the first protecting layer.

304, forming a second protecting layer on the metal traces and the first protecting layer.

Further, a plurality of the first hole and a plurality of the second connecting hole are formed on the second protecting layer. Each of the first holes is correspondingly positioned to one metal trace, each of the second connecting holes is correspondingly positioned and connected to one of the first connecting hole.

Specifically, forming a plurality of preset pattern metal traces by mask photo process.

305, forming a plurality of anodes interval positioned on the second protecting layer.

Further, each of the anodes is electrically connecting to the correspondingly drain electrode by the first connecting hole and the second connecting hole.

Further, each of the anodes comprises an anode main body and an anode connecting portion which bending toward and extending to the metal traces by the anode main body. The anode main body is positioned on the second protecting layer. Each of the anodes connecting portions is electrically connecting to a drain electrode by pass through the second connecting hole and the first connecting hole.

306, forming a pixel defining layer on the second protecting layer, the pixel defining layer is forming an accommodation region surround and above each of the anodes.

Further, forming a plurality of the second hole on the pixel defining layer. Each of the second holes is connecting to one of the first hole.

307, forming a light-emitting layer on each of the anodes, the light-emitting layer is accommodating in the accommodation region.

308, depositing to form a plurality of cathodes which may used to be touch electrode layer above the light-emitting layer, the cathodes are interval positioned; each of the cathodes is electrically connecting to the correspondingly metal trace.

Each of the cathodes is electrically connecting to the correspondingly metal trace by the second hole and the first hole. Above the each of the light-emitting layers is forming one cathode.

Further, each of the cathodes comprises a cathode main body and a cathode connecting portion which bending toward and extending to the metal traces by the cathode main body. The cathode main body is electrically connecting to the metal trace by pass through the second hole and the first hole

The first protecting layer is passivation layer and made by inorganic materials; the second protecting layer is planarization layer and made by organic materials; Or the first protecting layer is planarization layer and made by organic materials; the second protecting layer is passivation layer and made by inorganic materials.

The touch screen panel and method of manufacture thereof are provided by this disclosure. The traditional OLED display device is patterning entire cathode to form a plurality of cathodes. Each of cathodes is electrically connecting by metal trace and controller, which is the cathode also used to be a touch electrode layer of OLED touch screen. So that it does not need to position another touch electrode, reduces element, and decreases thickness of the touch screen panel, it beneficial to light-thin development.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A touch screen panel, comprising
a TFT array substrate;
a first protecting layer positioned on the TFT array substrate;
a plurality of metal traces interval positioned on the first protecting layer;
a second protecting layer covering the metal traces and the first protecting layer; and an anode, a pixel defining layer, a light-emitting layer and a plurality of interval positioned cathodes are sequentially positioned on the second protecting layer, the cathodes are used to be touch electrode layer, each of the cathodes is electrically connecting to the correspondingly metal trace.

2. The touch screen panel according to claim 1, wherein the first protecting layer is passivation layer and made by inorganic materials; the second protecting layer is planarization layer and made by organic materials.

3. The touch screen panel according to claim 1, wherein the first protecting layer is planarization layer and made by organic materials; the second protecting layer is passivation layer and made by inorganic materials.

4. The touch screen panel according to claim 1, wherein a first hole is formed on the second protecting layer, a second hole is formed on the pixel defining layer and connecting with the first hole, the cathode is electrically connecting with the metal trace by the first hole and the second hole.

5. The touch screen panel according to claim 4, wherein each of the cathodes comprises a cathode main body and a cathode connecting portion which extending by the cathode main body, the cathode main body is covering the light-emitting layer, the cathode connecting portion pass through the first hole and the second hole and is electrically connecting with the correspondingly metal trace.

6. The touch screen panel according to claim 1, wherein the a first connecting hole is formed on the first protecting layer, a second connecting hole is formed on the second protecting layer and connecting to the first connecting hole, the anode is electrically connecting to a drain electrode of the TFT array substrate according to the first connecting hole and the second connecting hole.

7. The touch screen panel according to claim 6, wherein each of the anodes comprises an anode main body and an anode connecting portion which extending by the anode main body, the anode main body is accommodating in the pixel defining layer, the anode main body is positioned between the second protecting layer and the light-emitting layer, the anode connecting portion pass through the second connecting hole and the first connecting hole for electrically connecting with the drain electrode such that achieves to electrically connection between the anode and the drain electrode.

8. The touch screen panel according to claim 1, wherein the touch screen panel further comprising a controller, the controller is electrically connected by the metal trace and the cathode, the controller has touch and display driving controlling function.

9. The touch screen panel according to claim 1, wherein materials of the metal trace is at least one of Cu, Ag, Al, Ti, Mo.

10. A method of manufacturing touch screen panel, comprising
providing TFT array substrate;
forming a first protecting layer on the TFT array substrate;
forming a plurality of metal traces interval positioned on the first protecting layer;
forming a second protecting layer covering the metal traces and the first protecting layer;
forming a plurality of anodes interval positioned on the second protecting layer;
forming a pixel defining layer on the second protecting layer, the pixel defining layer is forming an accommodation region surround and above each of the anodes;
forming a light-emitting layer on each of the anodes, the light-emitting layer is accommodating in the accommodation region;
forming a plurality of cathodes which could be touch electrode layer above the light-emitting layer, the cathodes are interval positioned, each of the cathodes is electrically connecting to the correspondingly metal trace.

11. The method of manufacturing touch screen panel according to claim 10, wherein in the step of “forming a second protecting layer on the metal traces and the first protecting layer”, which forming a plurality of first holes on the second protecting layer, and each of first holes is correspondingly positioned a metal trace; in the step of “forming a pixel defining layer on the second protecting layer, the pixel defining layer is forming an accommodation region surround and above each of the anodes”, which forming a plurality of second holes on the pixel defining layer, each of the second holes is connecting with the first hole, each of the cathodes is electrically connecting to the correspondingly metal trace by the first hole and the second hole.

12. The method of manufacturing touch screen panel according to claim 10, wherein the first protecting layer is passivation layer and made by inorganic materials; the second protecting layer is planarization layer and made by organic materials;
or the first protecting layer is planarization layer and made by organic materials; the second protecting layer is passivation layer and made by inorganic materials.
